(19) United States
(12) Patent Application Publication
(10) Pub. No.: US 2008/0160256 A1
(43) Pub. Date: Jul. 3, 2008

(54) REDUCTION OF LINE EDGE ROUGHNESS BY CHEMICAL MECHANICAL POLISHING

(76) Inventors: Robert L. Bristol, Portland, OR (US); Chris E. Barns, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/618,752

(22) Filed: Dec. 30, 2006

(51) Int. Cl. G03F 7/26; B32B 1/00

(52) U.S. Cl. 428/143; 430/323

(57) ABSTRACT

The present invention describes a method including: providing a wafer; applying a photoresist over the wafer; forming a first set of features in the photoresist; etching a hard mask below the photoresist to form a second set of features in the hard mask; removing the photoresist; etching a polysilicon below the hardmask to form a third set of features in the polysilicon; removing the hard mask; and reducing a line edge roughness in the third set of features.

### BACKGROUND OF THE INVENTION

1. Field of the Invention

The present invention relates to the field of semiconductor integrated circuit (IC) manufacturing, and more specifically, to a method of reducing line edge roughness (LER) of a polysilicon gate in a microprocessor.

2. Discussion of Related Art

The manufacturing of IC devices involves the sequential processing of a wafer to form or remove materials for each layer of the wafer. Various materials may be formed by processes, such as oxidation, chemical vapor deposition, sputter deposition, ion implantation, and electroplating. Certain materials may be removed, partially or completely, by processes, such as wet etch, dry etch, or polishing.

Photolithogaphy may be performed together with some of these processes to selectively process certain portions of the wafer. Photolithogaphy may involve about 35 masks to pattern all of the layers on the wafer. However, only those masks which are used for layers that define the features in the IC design having the tightest groundrules are considered critical. The critical layers typically include isolation, gate, contact, and first metal.

A mask may be fabricated by depositing an opaque material, such as chrome, on a transparent substrate, such as quartz, and then etching the chrome to form features that are 4 times larger than the desired size on the wafer.

The wafer is covered with a material called photoresist that is sensitive to radiation. An exposure tool, such as a wafer scanner, optically reduces the features 4 times while projecting radiation of the appropriate wavelength through the mask so as to print a latent image with the correct dimensions on the wafer. Many parameters of an IC device are monitored during fabrication to assure that the device will meet the performance and reliability specifications.

In particular, the performance of a microprocessor is strongly dependent on the channel length of the devices in the microprocessor. The channel length is determined by the critical dimension (CD) of the gate. The processes of photolithography and etch are used to define the gate CD during the fabrication of the microprocessor on a wafer.

The yield in fabricating a microprocessor is strongly impacted by variability in gate CD of the devices formed across the wafer. CD variability includes line edge roughness (LER). As gate CD is progressively scaled down with each new generation of a microprocessor, LER consumes an increasingly larger portion of the overall CD error budget.

Thus, what is needed is a method of reducing line edge roughness (LER) in a surface layer or underlying layer, such as of a polysilicon gate in a microprocessor.

### BRIEF DESCRIPTION OF THE DRAWINGS

FIG. 1 is an illustration of a flowchart of a method of reducing line edge roughness (LER) in a surface layer or an underlying layer, such as of a polysilicon gate in a microprocessor, according to an embodiment of the present invention.

### DETAILED DESCRIPTION OF THE PRESENT INVENTION

In the following description, numerous details, such as specific materials, dimensions, and processes, are set forth in order to provide a thorough understanding of the present invention. However, one skilled in the art will realize that the invention may be practiced without these particular details. In other instances, well-known semiconductor equipment and processes have not been described in particular detail so as to avoid obscuring the present invention.

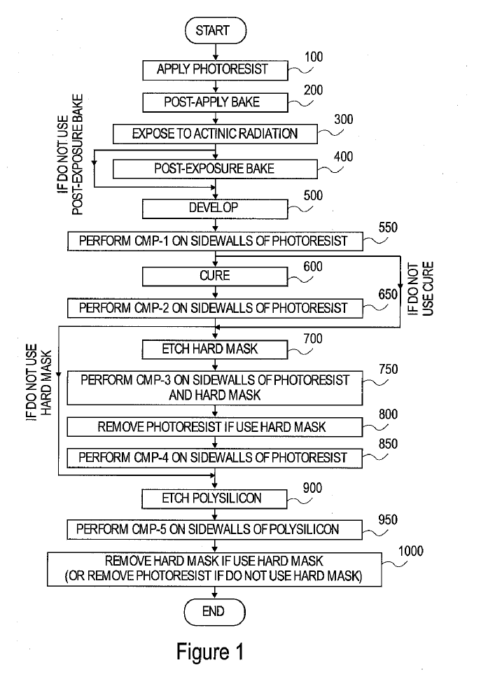

The present invention describes a method of using chemical mechanical polishing (CMP) brushing, or cleaning to reduce line edge roughness (LER) in a surface layer or an underlying layer, such as of a polysilicon gate in a microprocessor. A flowchart of an embodiment of the present invention is shown in FIG. 1.

A chemically-amplified (CA) photoresist is applied on a substrate, such as a wafer, in block 100. As described below in an embodiment of the resent invention, the photoresist may have a positive tone. However, in another embodiment of the present embodiment, the photoresist may have a negative tone.

A track tool may be used to spin the wafer and coat the photoresist. In an embodiment of the present invention, the photoresist has a thickness that may be selected from a range of 20-60 nanometers (nm). In another embodiment of the present invention, the photoresist has a thickness that may be selected from a range of 60-180 nm. In still another embodiment of the present invention, the photoresist has a thickness that may be selected from a range of 180-540 nm.

In an embodiment of the present invention, an antireflective coating (ARC) may be used. The ARC may be a bottom ARC (BARC) or a top ARC (TARC). The thickness of the ARC depends on the optical constants of the ARC and the photoresist as well as the thickness of the photoresist. The thickness of the ARC may be equivalent to half of the thickness of the photoresist or less. In an embodiment of the present invention, the bottom ARC may have a thickness of 10-30 nm. In another embodiment of the present invention, the bottom ARC may have a thickness of 30-90 nm. In an embodiment of the present invention, the bottom ARC may have a thickness of 90-270 nm.

The photoresist is post-apply baked (PAB) in block 200. In an embodiment of the present invention, the photoresist may be baked at 70-90 degrees Centigrade for 50-145 seconds. In another embodiment of the present invention, the photoresist may be baked at 90-110 degrees Centigrade for 35-105 seconds. In still another embodiment of the present invention, the photoresist may be baked at 110-130 degrees Centigrade for 25-75 seconds.

The photoresist is exposed in block 300 to actinic radiation. The actinic radiation may be provided by a mercury lamp or an excimer laser.

In an embodiment of the present invention, the actinic radiation may include near ultraviolet (NUV) light. In another embodiment of the present invention, the actinic radiation may include mid-ultraviolet (MUV) light. In still another embodiment of the present invention, the actinic radiation may include deep ultraviolet (DUV) light.

In an embodiment of the present invention, the DUV light has a wavelength of 248 nm, such as provided by a Krypton Fluoride (KrF) excimer laser source. In another embodiment of the present invention, the DUV light has a wavelength of 193 nm, such as provided by an Argon Fluoride (ArF) excimer laser source. In still another embodiment of the present invention, the DUV light has a wavelength of 157 nm, such as provided by a Fluorine (F₂) excimer laser source.

The exposure may be performed in a wafer stepper or a wafer scanner using conventional or “dry” lithography with a numerical aperture (NA) of 0.70-0.90 and a partial coherence (sigma) of 0.40-0.80. When immersion or “wet” lithography is used to improve resolution, the NA may be considerably higher, such as 0.90-1.30.

The exposure may be performed using conventional illumination or off-axis illumination (OAI). Use of OAI, such as annular illumination, dipole illumination, or quadrupole illumination, may improve resolution and depth of focus (DOF).

The exposure may be performed with a pupil filter (PF).

In an embodiment of the present invention, the exposure may be performed with a reticle that includes a binary mask, such as a chrome-on-glass (COG) mask. In another embodiment of the present invention, the exposure may be performed with a reticle that includes a phase-shifting mask (PSM). Most non-critical layers are exposed with one reticle, although a few critical layers, such as polysilicon gate layer, may require exposure with two reticles.

The PSM may be a strong PSM or a weak PSM. The more frequently used types of PSM include an alternating phase-shifting mask (AltPSM), an attenuated phase-shifting mask (AttPSM), and an embedded phase-shifting mask (EPSM).

The reticle, whether a binary mask or a PSM, may include optical proximity correction (OPC) to improve pattern fidelity. OPC may be rule-based, model-based, or a combination of the two methods. Serifs, dogbones, and jogs of various shapes and sizes may be selectively added to portions of features to minimize certain printing problems, including corner rounding and line shortening. Anti-scattering bars may also be added next to features to minimize certain printing problems.

Exposure to photons causes a photoacid generator (PAG) in the CA photoresist to decompose and generate acid.

In an embodiment of the present invention, a dose of 2-6 mJ/cm² may be used for exposure. In another embodiment of the present invention, a dose of 6-18 mJ/cm² may be used for exposure. In still another embodiment of the present invention, a dose of 18-54 mJ/cm² may be used for exposure.

The CA photoresist may be post-exposure baked (PEB) in block 400. In an embodiment of the present invention, the photoresist is baked at 90-110 degrees Centigrade for about 50-145 seconds. In another embodiment of the present invention, the photoresist is baked at 110-130 degrees Centigrade for about 35-105 seconds. In still another embodiment of the present invention, the photoresist is baked at 130-150 degrees Centigrade for about 25-75 seconds.

The post-exposure bake thermally activates an acid-catalyzed reaction in which an acid-labile protecting group on a polymer backbone of the CA photoresist is cleaved by acid and the polarity of the polymer backbone is changed from lipophilic to hydrophilic. During the deprotecting process, more acid is created as a byproduct, thus continuing the acid-catalyzed deprotection cycle.

Activation energy is a measure of a reactivity (to cleaving) of the acid-labile protecting group (on the polymer backbone of the CA photoresist) to the acid generated by decomposition of the PAG (in the CA photoresist) upon exposure to light.

In an embodiment of the present invention, the CA photoresist may be designed to have a high activation energy (low reactivity) which permits higher temperatures to be used for the post-apply bake and the post-exposure bake. A high-activation-energy CA photoresist has a more stable shelf-life and is more compatible with a manufacturable process. In particular, a high-activation-energy CA photoresist that is inadvertently heated during exposure is less likely to form volatile byproducts that may form undesirable deposits on nearby optical elements in the wafer stepper or wafer scanner.

In an embodiment of the present invention, the CA photoresist may be designed to have a low activation energy (high reactivity) which permits lower temperatures to be used for the post-apply bake and the post-exposure bake. A low-activation-energy CA photoresist is less affected by the length of time (delay) that occurs between the exposure and the post-exposure bake. In another embodiment, a post-exposure bake may not be needed for a low-activation-energy CA photoresist.

The photoresist is developed in block 500. The exposed portions of the photoresist (if positive tone) become soluble in an aqueous alkaline developer, such as tetramethyl-ammonium hydroxide (TMAH) with a concentration such as 0.26 N. The sidewall slope or angle of a feature printed in the photoresist may be 84-89 degrees after develop.

If desired, especially prior to undergoing a dry etch, the photoresist may be cured in block 600. Various pressures, including a vacuum, may be used for the cure. In an embodiment of the present invention, a soft vacuum, such as a pressure of 10⁻³-10⁻¹ Torr, may be used.

In an embodiment of the present invention, the photoresist is cured using thermal energy only, such as with a bake. In another embodiment of the present invention, the photoresist is cured with a bake combined with a flood exposure of ultraviolet light. In still another embodiment of the present invention, the photoresist is cured with a bake combined with a flood exposure of electrons.

Various factors will influence the choice of tool parameters and process parameters for the flood exposure of ultraviolet light or electrons. In an embodiment of the present invention, the optimal conditions will depend upon the rheological properties of the photoresist. The properties of a surface layer and an underlying layer, such as electrical conductivity, thermal conductivity, and extent of mismatch in coefficient of thermal expansion, may also affect whether the photoresist will cure satisfactorily. Depending upon the actual parameters selected, the photoresist may soften, flow, dry up, wrinkle, outgas, form a crust, peel, crack, crater, or cross-link.

In another embodiment of the present invention, the optimal energy and dose may depend upon a thickness of the photoresist. A higher energy will increase the penetration depth of the incident light or electrons. Thus, a higher energy may be needed to cure a thicker photoresist.

In another embodiment of the present invention, the optimal energy and dose may depend upon a volume of the photoresist. A higher dose may be needed to cure a larger volume of photoresist.

In still another embodiment of the present invention, the optimal energy and dose may depend upon the size and shape of the features that have been formed in the photoresist. Dose is equivalent to a product of the flood exposure current and the flood exposure time. Photoresist with an isolated space may have a large volume, photoresist with nested features, such as multiple lines and spaces, may have an intermediate volume, while photoresist with an isolated line may have a small volume.

After the photoresist has been appropriately cured as needed, a dry etch may be performed to replicate or transfer a pattern from the surface layer to the underlying layer. Thus, the surface layer serves as an “in situ” mask to define the same or similar pattern in the underlying layer. The etch rate of the surface layer should be lower than the etch rate of the underlying layer.

An etch selectivity or ratio may be defined as the etch (removal) rate of the underlying layer divided by the etch (removal) rate of the surface layer. In an embodiment of the present invention, etch selectivity may be improved by changing etch chemistry. In another embodiment of the present invention, etch selectivity may be improved by changing reactor parameters. In still another embodiment of the present invention, etch selectivity may be improved by changing process flow or process sequence. In yet another embodiment of the present invention, etch selectivity may be improved by changing integration scheme, including materials, thicknesses, separations, overlaps, and layouts.

In an embodiment of the present invention, the etch selectivity for polysilicon gate layer may be selected from a range of 2:1-4:1. In another embodiment of the present invention, the etch selectivity for polysilicon gate layer may be selected from a range of 4.1-6:1. In still another embodiment of the present invention, the etch selectivity for polysilicon gate layer may be selected from a range of 6:1-8:1.

In an embodiment of the present invention, the surface layer may be photoresist while the underlying layer may be polysilicon. Then, the polysilicon (below the photoresist) may be etched at block 900 to form a gate having a desired width or critical dimension (CD).

In an embodiment of the present invention, the gate may be patterned with only one reticle (poly gate). In another embodiment (not shown) of the present invention, the gate may be patterned with two reticles: a first reticle (poly gate) to define the polysilicon with an initially larger width or CD, followed by a second reticle (trim) to further shrink the polysilicon to a subsequently smaller width or CD. Next, the photoresist may be removed and the wafer may be cleaned.

In an embodiment of the present invention, the surface layer may be photoresist while the underlying layer may be a hard mask. The hard mask is stacked over the polysilicon. Then, a first dry etch in block 700 may be used to replicate or transfer the pattern from the photoresist to the underlying hard mask. After removal of the photoresist in block 800, a second dry etch in block 900 may be used to replicate or transfer the pattern from the hard mask to the polysilicon below.

In an embodiment of the present invention, the gate may be patterned with only one reticle (poly gate). In another embodiment (not shown) of the present invention, the gate may be patterned with two reticles: the first reticle (poly gate) to define the hard mask (stacked over the polysilicon) with the initially larger width or CD, followed by the second reticle (trim) to further shrink the hard mask (stacked over the polysilicon) to the subsequently smaller width or CD. Next, the photoresist may be removed and the wafer may be cleaned.

Line edge roughness (LER) may occur along a length (or larger dimension) of adjacent and parallel features (troughs or islands) that have been patterned in a surface layer or underlying layer. In an embodiment of the present invention, the adjacent and parallel features that have been patterned are developed in photoresist. In another embodiment of the present invention, the adjacent and parallel features are etched in hard mask. In still another embodiment of the present invention, the adjacent and parallel features are etched in polysilicon. In yet another embodiment of the present invention, the adjacent and parallel features form polysilicon gates in a microprocessor.

In an embodiment of the present invention, line edge roughness may occur along a length (or larger dimension) selected from a scale or range of 20-50 nm. In another embodiment of the present invention, line edge roughness may occur along a length (or larger dimension) selected from a scale or range of 50-125 nm. In still another embodiment of the present invention, line edge roughness may occur along a length (or larger dimension) selected from a scale or range of 125-300 nm. The line edge roughness for a length selected from a scale or range of 50 nm or greater may also be called a linewidth roughness (LWR).

The line edge roughness may appear as irregularities, unevenness, raggedness, or waviness in the sidewalls of the features. The line edge roughness may include a combination of notches or indentations (resulting in a smaller width or CD that is localized) and protrusions (resulting in a larger width or CD that is localized) in the surface layer or underlying layer. The effect of line edge roughness on performance and reliability of a fabricated devices such as at a gate level, is usually more severe for notches or indentations than for protrusions.

In an embodiment of the present invention, chemical mechanical polishing (CMP), brushing, or cleaning may be performed at any one step, or at multiple steps, of the process flow, including at block 550, block 650, block 750, block 850, and block 950, to reduce line edge roughness.

In another embodiment of the present invention, the CMP, brushing, or cleaning may be performed one time, or multiple times, at each step of the process flow.

In an embodiment of the present invention, the CMP, brushing, or cleaning may reach across, over, or around the sidewalls of adjacent long and parallel features (troughs or islands) located in the surface layer or underlying layer.

In another embodiment of the present invention, the CMP, brushing, or cleaning may reach downwards, upwards, or sideways along the sidewalls of adjacent long and parallel features (troughs or islands) located in the surface layer or underlying layer.

In still another embodiment of the present invention, the CMP, brushing, or cleaning may straighten, flatten, or smooth the sidewalls of adjacent long and parallel features (troughs or islands) in an orientation (or direction) that is parallel to the length (or larger dimension) of the long features (troughs or islands) without eroding a top (or upper) portion of the long features (troughs or islands).

In yet another embodiment of the present invention, the CMP, brushing, or cleaning may straighten, flatten, or smooth the sidewalls of the long features (troughs or islands) in an orientation (or direction) that is parallel to the depth of the troughs (or height of the islands) without eroding a top (or upper) portion of the long features (troughs or islands).

The CMP, brushing, or cleaning should be optimized to minimize dishing, minimize erosion, minimize edge roll-off, and reduce defect level. A polish selectivity or ratio may be defined as the polish (removal) rate of the underlying layer divided by the polish (removal) rate of the surface layer. The polish selectivity may be increased or decreased in order to optimize the CMP, brushing, or cleaning.

In an embodiment of the present invention, polish (removal) rate and uniformity may be altered by changing polish slurry chemistry, including pH, particle abrasiveness, and particle size distribution. In another embodiment of the present invention, polish (removal) rate and uniformity may be altered by changing polish pad characteristics, including thickness, density, porosity, hardness, stiffness, and roughness. In still another embodiment of the present invention, a stacked pad, including a more rigid upper portion (located closer to fresh slurry and wafer) attached to or arranged over a more flexible lower portion (located farther from fresh slurry and wafer), may be used. In yet another embodiment of the present invention, polish (removal) rate and uniformity may be altered by changing polish tool configuration, process tool parameters, and polish process parameters, including slurry flowrate, pad conditioning (in situ or ex situ), belt or platen temperature, contact pressure, and relative linear velocity.

In an embodiment of the present invention, the CMP, brushing, or cleaning is performed at block 550 on sidewalls of the photoresist after develop, but before cure.

In another embodiment of the present invention, the CMP, brushing, or cleaning is performed at block 650 on sidewalls of the photoresist after develop and subsequent cure.

In still another embodiment of the present invention, the CMP, brushing, or cleaning is performed at block 750 on sidewalls of the cured photoresist and sidewalls of the underlying hard mask after dry etch of the hard mask.

In yet another embodiment of the present invention, the CMP, brushing, or cleaning is performed at block 850 on sidewalls of the hard mask after dry etch of the hard mask and removal of the overlying photoresist.

In a further embodiment of the present invention, the CMP is performed at block 950 on sidewalls of the polysilicon after dry etch of the polysilicon. If the hard mask had been used, the photoresist may be removed before, or after, dry etch of the polysilicon. If the hard mask had not been used, the photoresist is removed after the dry etch of the polysilicon.

In an embodiment of the present invention, at least the critical portions of all of the polysilicon gates on a wafer have the same orientation (or direction). In another embodiment of the present invention, a design for a semiconductor integrated circuit (IC) chip has a layout in which at least the critical portions of all of the features on the polysilicon gate layer are arranged as parallel lines.

In an embodiment of the present invention, the CMP may be performed in a direction that is parallel to at least the critical portions of all the polysilicon gates on the wafer. In another embodiment of the present invention, a linear CMP tool may be used. The linear CMP tool may include a single belt or multiple belts.

In an embodiment of the present invention, a parallel polish zone of a rotary CMP tool may be used. The rotary CMP tool may include a pad-below-wafer (face down) tool configuration or a pad-above-wafer (face up) tool configuration. The rotary CMP tool may include a single head or multiple heads.

In an embodiment of the present invention, brushing or cleaning with a roller or a brush may be performed in a direction that is parallel to at least the critical portions of all the polysilicon gates on the wafer. In another embodiment of the present invention, a counter-rotating, double-roller tool or a counter-rotating, double-brush tool may be used.

In an embodiment of the present invention, the line edge roughness is reduced by performing the CMP with a slurry that includes nano-particles or nano-whiskers that are at least partially suspended in a liquid, solution, suspension, or colloid. In another embodiment of the present invention, the line edge roughness is reduced by performing CMP with a pad that includes nano-fibers or nano-tubes attached to a pad surface that is at least partially immersed in a liquid, solution, suspension, or colloid. In still another embodiment of the present invention, the line edge roughness is reduced by brushing or cleaning with a roller or a brush that includes nano-fibers or nano-tubes attached to a roller or brush that is at least partially immersed in a liquid, solution, suspension, or colloid.

In an embodiment of the present invention, the nano-particles, nano-whiskers, nano-fibers, and nano-tubes are characterized by having a width (or shorter dimension) that is selected from a range of 3-10 nanometers (nm). In an embodiment of the present invention, the nano-particles, nano-whiskers, nano-fibers, and nano-tubes are characterized by having a width (or shorter dimension) that is selected from a range of 10-25 nm. In an embodiment of the present invention, the nano-particles, nano-whiskers, nano-fibers, and nano-tubes are characterized by having a width (or shorter dimension) that is selected from a range of 25-50 nm.

In an embodiment of the present invention, the nano-particles, nano-whiskers, nano-fibers, and nano-tubes are characterized by having a width (or shorter dimension) that is 10-20% of the separation (or distance) between adjacent, parallel, long features (troughs or islands) located in a surface layer or underlying layer. In another embodiment of the present invention, the nano-particles, nano-whiskers, nano-fibers, and nano-tubes are characterized by having a width (or shorter dimension) that is 20-40% of the separation (or distance) between adjacent, parallel, long features (troughs or islands) located in a surface layer or underlying layer. In still another embodiment of the present invention, the nano-particles, nano-whiskers, nano-fibers, and nano-tubes arc characterized by having a width (or shorter dimension) that is 40-80% of the separation (or distance) between adjacent, parallel, long features (troughs or islands) located in a surface layer or underlying layer. In yet another embodiment of the present invention, the nano-particles, nanowhiskers, nano-fibers, and nano-tubes will fit in between adjacent parallel long features (troughs or islands).

In an embodiment of the present invention, the value of the line edge roughness in the surface layer or underlying layer is reduced by 15-25% (3-sigma). In another embodiment of the present invention, the value of the line edge roughness in the surface layer or underlying layer is reduced by 25-40% (3-sigma). In still another embodiment of the present invention, the value of the line edge roughness in the surface layer or underlying layer is reduced by 40-65% (3-sigma).

In an embodiment of the present invention, the line edge roughness may be reduced to a value selected from a range of 4-8 nm. In another embodiment of the present invention, the line edge roughness may be reduced to a value selected from a range of 2-4 nm. In still another embodiment of the present invention, the line edge roughness may be reduced to a value selected from a range of 1-2 nm.

In another embodiment of the present invention, the line edge roughness in the surface layer and underlying layer is reduced without altering a width or CD of the long features (troughs or islands) located in the surface layer or underlying layer.

In still another embodiment of the present invention, the line edge roughness in the surface layer and underlying layer is reduced without altering a volume of the long features (troughs or islands) located in the surface layer or underlying layer.

In another embodiment of the present invention, a reduction in line edge roughness (3-sigma) of a feature is less at final check CD (FCCD) than at develop check CD (DCCD). Develop check CD is the CD of the feature after develop. Final check CD is the CD of the feature after etch.

Many embodiments and numerous details have been set forth above in order to provide a thorough understanding of the present invention. One skilled in the art will appreciate that many of the features in one embodiment are equally applicable to other embodiments. One skilled in the art will also appreciate the ability to make various equivalent substitutions for those specific materials, processes, dimensions, concentrations, etc. described herein. It is to be understood that the detailed description of the present invention should be taken as illustrative and not limiting, wherein the scope of the present invention should be determined by the claims that follow.

Thus, we have described a method of using chemical mechanical polishing (CMP), brushing, or cleaning to reduce line edge roughness (LER) in a surface layer or underlying layer, such as of a polysilicon gate in a microprocessor.

We claim:

1. A method comprising:
providing a wafer;
applying a photoresist over said wafer;
forming a first set of features in said photoresist;
etching a hard mask below said photoresist to form a second set of features in said hard mask;
removing said photoresist;
etching a polysilicon below said hardmask to form a third set of features in said polysilicon;
removing said hard mask; and
reducing a line edge roughness in said third set of features.

2. The method of claim 1 wherein said third set of features comprises troughs that are long and parallel.

3. The method of claim 1 wherein said third set of features comprises islands that are long and parallel.

4. The method of claim 1 wherein said reducing said line edge roughness in said third set of features comprises performing chemical mechanical polishing on sidewalls of said first set of features in said photoresist.

5. The method of claim 1 wherein said reducing said line edge roughness in said third set of features comprises performing chemical mechanical polishing on sidewalls of said second set of features in said hardmask.

6. The method of claim 1 wherein said reducing said line edge roughness in said third set of features comprises performing chemical mechanical polishing on sidewalls of said third set of features in said polysilicon.

7. The method of claim 1 wherein said reducing said line edge roughness in said third set of features comprises brushing sidewalls of said first set of features in said photoresist.

8. The method of claim 1 wherein said reducing said line edge roughness in said third set of features comprises brushing sidewalls of said second set of features in said hardmask.

9. The method of claim 1 wherein said reducing said line edge roughness in said third set of features comprises brushing sidewalls of said third set of features in said polysilicon.

10. The method of claim 1 wherein said reducing said line edge roughness in said third set of features comprises cleaning sidewalls of said first set of features on said photoresist.

11. The method of claim 1 wherein said reducing said line edge roughness in said third set of features comprises cleaning sidewalls of said second set of features in said hardmask.

12. The method of claim 1 wherein said reducing said line edge roughness in said third set of features comprises cleaning sidewalls of said third set of features in said polysilicon.

13. The method of claim 1 wherein said reducing said line edge roughness in said third set of features comprises performing chemical mechanical polishing with a slurry comprising nano-particles.

14. The method of claim 1 wherein said reducing said line edge roughness in said third set of features comprises performing chemical mechanical polishing with a slurry comprising nano-whiskers.

15. The method of claim 1 wherein said reducing said line edge roughness in said third set of features comprises performing chemical mechanical polishing with a pad comprising nano-fibers.

16. A method comprising:
forming features in polysilicon, said features being adjacent, parallel and long;
smoothing sidewalls of said features; and
reducing a line edge roughness in said features.

17. The method of claim 16 wherein said smoothing comprises chemical mechanical polishing.

18. An apparatus comprising:
a pad, said pad comprising nano-fibers;
a slurry disposed over said pad, said slurry comprising nano-particles and nano-whiskers; and
a wafer disposed over said slurry, said wafer comprising features, said features having a reduced line edge roughness of 2-4 nanometers.

19. The apparatus of claim 18 wherein said nano-fibers are disposed between features that are adjacent, parallel, and long.

20. The apparatus of claim 18 wherein said nano-particles are disposed between features that are adjacent, parallel and long.

21. The apparatus of claim 18 wherein said nano-whiskers are disposed between features that are adjacent, parallel, and long.
